(19) United States
(12) Patent Application Publication
(10) Pub. No.: US 2010/0012169 A1
(43) Pub. Date: Jan. 21, 2010

(54) Energy Recovery of Secondary Obscuration

(75) Inventors: John Steffen Jensen, Santa Cruz, CA (US); Mark McDonald, Milpitas, CA (US)

Correspondence Address: THE MUELLER LAW OFFICE, P.C., 12951 Harwick Lane, San Diego, CA, 92130, US

(73) Assignee: SOLFOCUS, INC., Mountain View, CA (US)

(21) Appl. No.: 12/176,341

(22) Filed: Jul. 19, 2008

(51) Int. Cl. H01L 31/042

(52) U.S. Cl. 136/246

(57) ABSTRACT

A solar energy system is provided to capture an increased amount of solar energy in an area. Methods and devices to collect obscured solar radiation and covert it into usable electrical energy are described. The devices include a major concentrated solar energy system combined with a minor solar energy system. In one embodiment, the minor solar energy system includes a primary mirror, secondary mirror and a second photocell. Primary and secondary mirrors of a minor solar energy system are defined by their location, at least a portion of which may be substantially within the concave region of the secondary mirror of a major solar energy system. The electrical connection from the minor solar energy system to the major solar energy system is described. Methods for making minor solar energy system are provided.

### BACKGROUND OF THE INVENTION

The present invention relates generally to the field of solar energy collection. In particular, the present invention relates to the field of concentrated photovoltaics (CPV). Solar energy collection has already proven to be a very effective energy option. A particular type of module utilized in a conventional solar system employs a photovoltaic (PV) cell. PV cells may be configured into modules and arrays that convert solar irradiation into usable electrical power for a wide variety of applications. As a power generation and distribution solution, PV modules can provide an alternative or supplement to traditional grid-supplied electricity or can serve as a stand-alone source of power in remote regions.

Concentrating solar collectors reduce the need for large semiconductor substrates by concentrating solar radiation (i.e., sun rays) using, e.g., a parabolic reflectors or lenses that focus the beams, creating a more intense beam of solar energy that is directed onto a small PV cell. Thus, concentrating solar collectors have an advantage over flat-panel collectors in that they utilize substantially smaller amounts of semiconductor. Another advantage that concentrating solar collectors have over flat-panel collectors is that they are more efficient at generating electrical energy. Two element CPV systems comprised of a primary mirror for collecting solar radiation and a secondary mirror for focusing the collected irradiation onto a non imaging optical concentrator or directly onto a PV cell are known in the art.

As the use of CPV systems becomes more widespread, there exists a need to optimize the efficiency of these systems. CPV and related solar energy systems are rendered less efficient by the loss of energy from irradiance striking the rear surface of the secondary mirror. The amount of energy loss caused by the obscuration by the secondary mirror is dependent on the size of the mirror. There exists a need in the art to make CPV systems more efficient and utilize more of the solar radiation striking the solar energy collection unit.

### BRIEF SUMMARY OF THE INVENTION

The present invention provides a solar energy system comprising a substantially planar surface capable of allowing solar radiation to pass through it. The solar energy system of this invention provides a first and second solar energy collection system. In one embodiment of this invention, the solar energy system provides a first and second photocell for receiving solar energy. The first photocell may receive a portion of solar radiation. The second photocell may receive a second portion of the solar radiation that is not collected by the first photocell. The first and second photocells then may convert a substantial amount of the received solar radiation into usable electricity.

The present invention may receive reflected or unreflected solar radiation. The second photocell may be a flat panel or a multi-junction cell or any other solar to electrical energy converting material known in the art. The second solar energy system may comprise an optical polymer coating on the outer surface of the second primary mirror. The optical polymer coating may be further treated to function as the secondary mirror of the first solar energy system for directing solar radiation to the first photocell.

The electricity generated by the first and second photocells may be conducted along parallel wiring systems or may be conducted along the same wiring system. A portion of the wiring may be imbedded in the optical polymer coating. The solar energy system of this invention may be made by providing a substantially planar surface capable of allowing solar radiation to pass through it, and a first concave mirror for reflecting a first portion of the solar radiation. The method of making this invention further comprises providing a first convex mirror for reflecting the first portion of the solar radiation reflected by the first concave mirror and providing a first photocell for receiving the first portion of the solar radiation reflected by both the first concave mirror and the first convex mirror. A second photocell for receiving a second portion of the solar radiation not reflected by the first mirror is then provided. This method results in generating a first electrical current from the major photocell and generating a second electrical current from the minor photocell.

### BRIEF DESCRIPTION OF THE DRAWINGS

In order to understand the invention and to see how it may be carried out in practice, a number of embodiments will now be described, by way of non-limiting examples only, with reference to the accompanying drawings in which:

FIG. 1 shows a schematic cross sectional view of a CPV system known in the art.

FIG. 2 shows a schematic cross sectional view of an embodiment of the solar energy system of this invention.

FIG. 3 shows a schematic cross section view of a portion of an alternative embodiment of the minor solar energy system of this invention.

FIGS. 4A-D are diagrams for a method of making a two layer mirror optimized for reflection in either direction.

FIGS. 5A and B show schematic cross section views of alternative embodiments of the minor solar energy system comprising A, an optical port, and B a two sided flat panel for collecting solar energy reflected from a mirror and directly from the sun.

FIGS. 6A and B depict a schematic view of alternative embodiments of the electrical conductivity from major and minor solar energy systems of this invention.

FIG. 7 shows a block diagram of a method of making a two sided mirrored surface optimized for reflection in two directions.

### DETAILED DESCRIPTION OF THE INVENTION

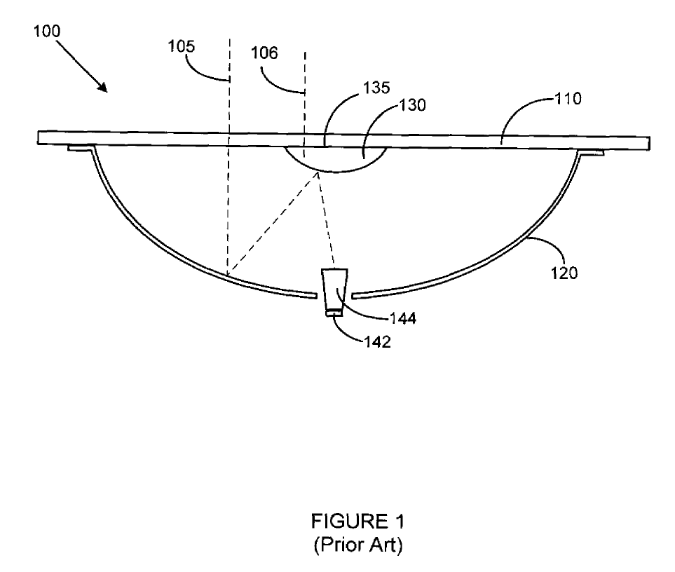

Reference will now be made in detail to embodiments of the disclosed invention, one or more examples of which are illustrated in the accompanying drawings. FIG. 1 illustrates a solar concentrator system of the type known in the art. In FIG. 1, the solar concentrator system (100) comprises a protective front panel (110) through which solar radiation (105) enters the system, a primary mirror (120) a secondary mirror (130), a non-imaging concentrator (144) and a primary solar photocell (142). The primary mirror reflects incoming light to a secondary mirror, which then reflects the light to a non-imaging concentrator. The non-imaging concentrator (144) delivers the light to a solar photocell (142). It can be seen that solar radiation (106) striking the rear surface of the primary mirror (135) is prevented from reaching the photocell (142).

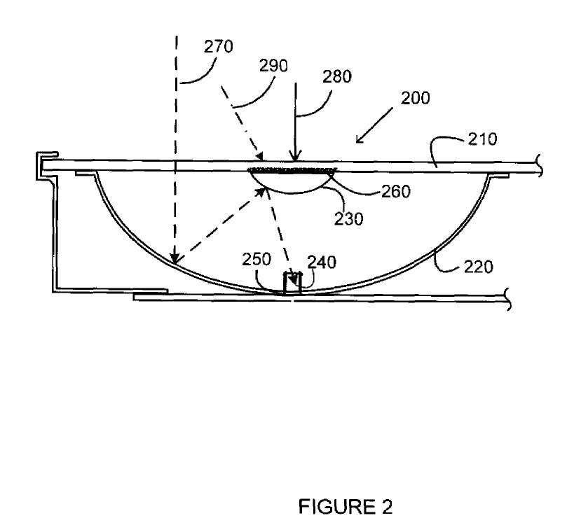

The present invention provides for electrical power to be generated locally using a solar energy system that is comprised of a major solar energy system and a minor solar energy system. In one embodiment of this invention, the minor solar energy system may be comprised of a photocell (260) interposed between the mechanical attachment surface of the secondary mirror (230) and the protective front panel (210) as shown in FIG. 2. The photocell may be crystalline or amorphous. The photocell may be a single junction, e.g., c-Si, CIGS, CdTe, a-Si, polySi, mc-Si or it may be a multi-junction e.g., SiGe, mc-Si, a-Si triple junction, mc-Si, a-Si tandem. The material used to attach the photocell to the front panel should be at least translucent, preferably transparent. The secondary mirror may be attached to the underside of the flat photocell by, for example, adhesive or mechanical methods. The photocell may be able to convert direct irradiation (280) and scattered irradiation (290) into useable electrical energy. One aspect of this invention is that energy recovered from the area obscured by the secondary mirror of the major solar energy system may increase the amount of electricity generated from an area, and would also enable the development of two element reflecting solar energy collectors with secondary mirrors of greater area.

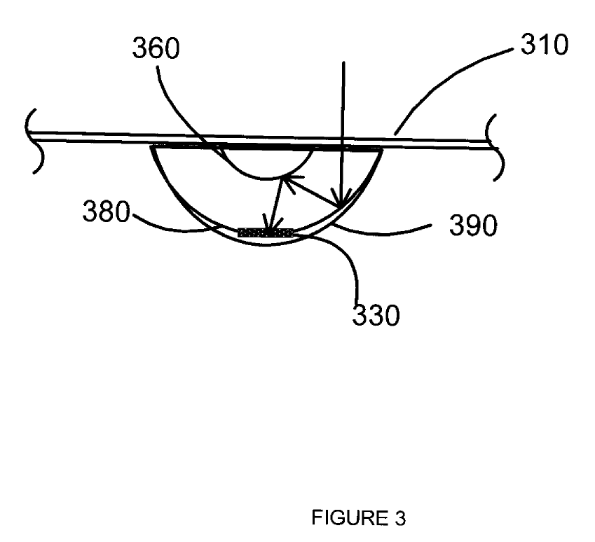

An alternative embodiment of this invention shown in FIG. 3 provides for a minor solar energy system comprised of a dual mirror concentrating system located between a portion of the secondary mirror of the major solar energy system (390) and a protective front panel (310). In this embodiment, the minor solar energy system comprises a minor primary mirror (380), located on the concave back side of the secondary mirror of the major solar energy system (390), a minor secondary mirror (360) affixed to the front panel, (380) and optionally, a photocell (330) located approximately at the vertex of the minor primary mirror (380). The photocell of the minor solar energy system may be a multi-junction cell. The photocell of the minor solar energy system may be mounted to collect solar radiation at a focus point near the center of second primary mirror of the secondary solar energy system. In one embodiment, the primary mirror of the minor solar energy system may comprise two oppositely oriented mirrored layers, wherein the convex, front (390) layer is the secondary mirror of the major solar energy system and the concave back (380) layer is the primary mirror of the minor solar energy system. In still another embodiment, the solar energy system of this invention may further comprise a non-imaging rod (not shown) to collect solar radiation from the secondary mirror of the minor solar energy system.

In another embodiment of this invention, a two element optical system located above the secondary mirror of the primary solar energy system may be a solid optical element. The solid optical element may be a monolithic molded optic, made of glass or other transparent material. The optical system may be aplanatic and the primary and secondary reflectors may the first and second surface of the solid optical element respectively

The secondary mirror of the major solar energy system and the primary mirror of the minor solar energy system may be formed from a single substrate. In one embodiment of this invention the shape of the two mirrors may be independently optimized to function as required. The shape of the minor primary mirror (390) may be substantially parabolic to concentrate solar radiation onto the minor secondary mirror (360). The shape of the major secondary mirror (380) may be substantially hyperbolic in order to collect a maximum amount of radiation reflected from the major primary mirror (not shown) and direct it towards the major photocell (not shown). In one embodiment the substrate may be made by injection molding, resulting in deep meniscus lens. In this way the concave surface of the substrate may be made substantially parabolic and the convex surface may be made substantially hyperbolic. After injection molding, the convex front and concave back surfaces may each be coated to form a mirror surface.

One embodiment for the method for making a solar energy system comprises placing a liquid optical coating into a mold that conforms to the shape of the first secondary mirror and is substantially hyperboloid, then inserting a substrate into the mold that conforms to the shape of the second concave primary mirror and is substantially parabolic. The liquid optical coating may then be polymerized. A mirror surface may then be applied to the convex surface of the optical coating. The surface of the substrate may be may be optionally mirrored on the convex front side prior to insertion into the liquid optical coating or the concave back side at any time in the manufacturing process

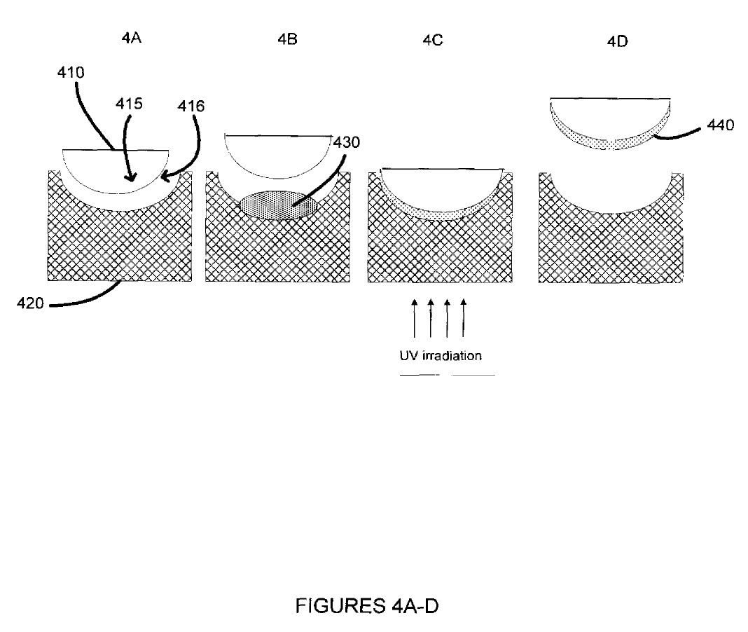

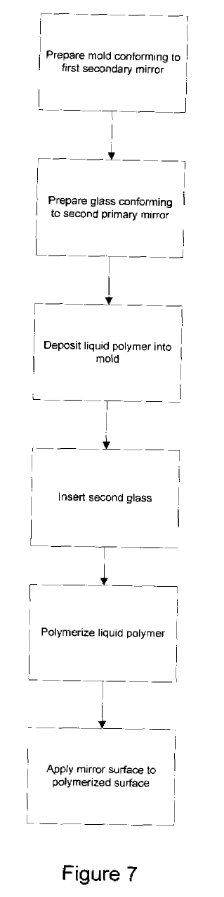

In another embodiment, the two mirror layers may be formed from a single substrate by a polymerization process (FIGS. 4A-4D). In FIG. 4A of this process, a mold (420) may be created into the desired shape, such as a substantially hyperbolic shape, next in the step shown in FIG. 4B, a liquid monomer (430) may be added to the mold. A curved transparent substrate (410) may be created into the desired shape, such as a substantially parabolic shape. The transparent substrate may be coated to have a mirrored surface before or after the application of a liquid monomer. A mirror surface may be applied to the concave (415) or convex (416) side of the transparent substrate (410). The transparent substrate may be placed in the mold comprising the liquid monomer (430). Polymerization of the liquid monomer, such as by heat or irradiation (FIG. 4C), results in a hardened surface comprising the shape of the mold onto the convex side of the transparent substrate. The hardened surface (FIG. 4D, 440) may then be separately treated with a mirror surface by a process consistent with the hardened surface process limits. A block diagram of this process is shown below in FIG. 7.

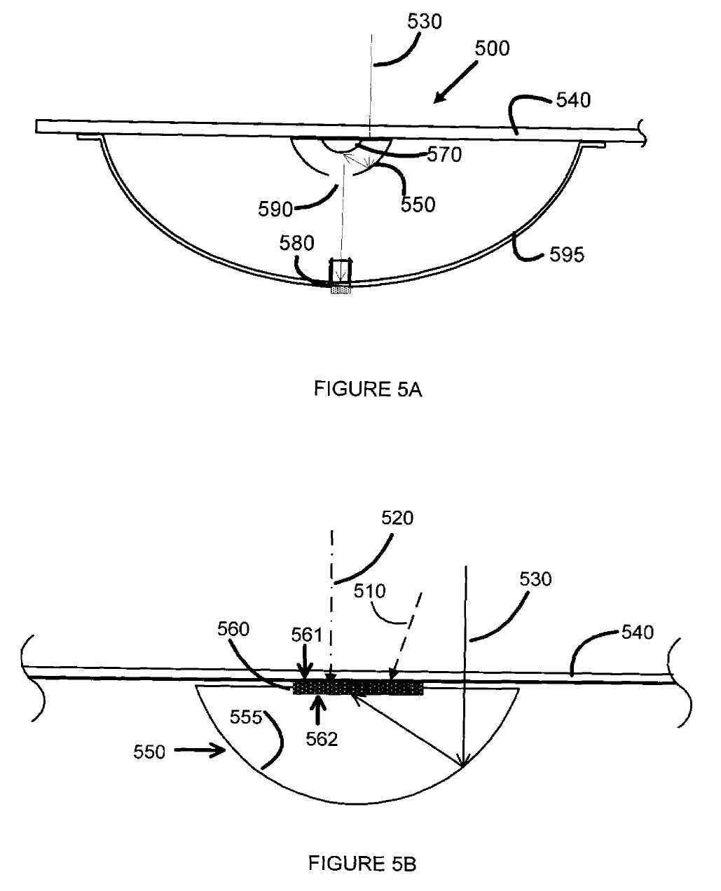

In one embodiment of this invention the optical system of the minor solar energy system may be housed in the area bounded by the secondary mirror of the major solar energy system and the protective front panel. This is seen in FIG. 5A. The irradiance (530) collected by the minor solar energy system may be passed through an optical port (590) to the major solar energy system onto the photocell (580) of the major solar energy system. The optical port (590) may be an aperture in the vertex of the secondary mirror (550) of the major solar energy device. One aspect of optical porting is that the use of a second photocell and transportation of electrical energy with wiring is avoided. The optical port would preferably occupy a substantially unirradiated region on the secondary mirror of the major solar energy system. In one embodiment of this invention, a relay mirror may be used to conduct the irradiation collected by the minor solar energy system to the photocell of the major solar energy system. The relay mirror may be either monolithic or assembled.

In this embodiment of this invention, solar energy received by the minor solar energy system may be focused onto the photocell of the major solar energy system. In one embodiment the invention, a cut out in the secondary mirror of the major solar energy system would permit light received by a minor energy system to be directed to the photocell of the major solar energy system. This approach need not impact the performance of the major solar energy system as the projection onto the secondary mirror of the area cutout out of the primary mirror to house the major photocell defines an unused region of the secondary mirror. Under ideal tracking conditions, the unused central region may be about 6 mm in diameter. Allowing for tracking errors of up to about 1.75 degrees, the region always free of optical irradiance may reduced to about 3.0 mm for some embodiment of this invention.

In another embodiment of this invention shown in FIG. 5B, the back surface (555) of the secondary mirror (550) of the major solar energy system may serve to concentrate solar energy to a photocell (560) without any modification to the shape of the secondary mirror (550) of the major solar energy system One aspect of this embodiment is that the back surface of the secondary mirror of the major solar energy system may concentrate the solar energy about 50-fold. This solar energy (530) may be directed onto a photocell (560) affixed to the front cover panel (540). The photocell may be for example a c-Si concentrator cell. In one embodiment of this invention, the photocell may convert direct solar energy received at the back surface (562) of the secondary mirror as well as direct (520) and indirect (510) solar energy from the sun received at the front side (561) of the photocell. In one embodiment of this invention, the attachment of the secondary mirror may be transparent for this use.

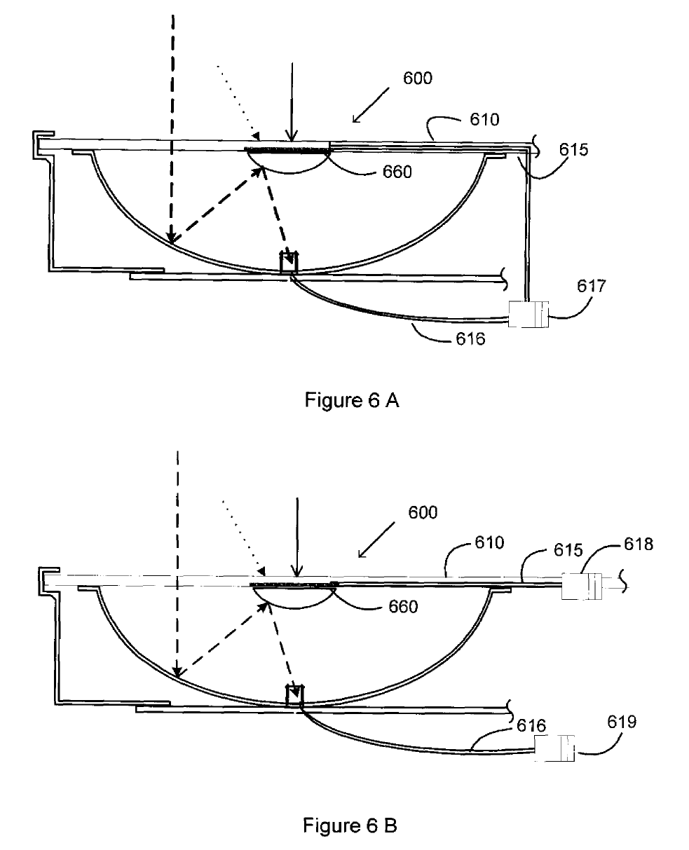

In one embodiment electrical energy from the minor solar energy system may be brought to the electrical system of the major solar energy system by the use of additional wiring as shown in FIGS. 6A and 6B. This wiring (615) may present a small cross-section on the protective front panel (610) under typical tracking conditions. The wiring may be above, below or imbedded in the protective front panel. High aspect ratio wiring fashioned from highly conductive metals may be used in this application. The aspect of the wiring may be made as a wedge to result in shallow reflected angles still within the acceptance angle of the main optical system. In another embodiment, transparent conductors, for example Indium Tin Oxide (ITO), may be fashioned on the cover glass and used to conduct electricity from the minor solar energy system to the main electrical wiring system of the major solar energy device. Electrical energy generated from the minor solar energy system may be derived from. Solar radiation that is obscured by the secondary mirror of major solar energy system may be combined electrically to the major electrical system via an electrical network. In one embodiment (FIG. 6B) the electrical network (615 and 618) used to conduct electricity generated by the minor solar energy system may be parallel to the electrical network used to conduct electricity generated by the major solar energy system (616 and 619). In another embodiment the electrical network may be connected at each photovoltaic cell (PVC) unit as shown in FIG. 6A (615, 616 and 617), or alternatively, a group of two or more major photovoltaic cells may be connected to a group of separately connected minor photovoltaic cells.

Although embodiments of the invention have been discussed primarily with respect to specific embodiments thereof, other variations are possible. For example, while the invention has been described with respect to solar energy collectors, the invention may applied to the recovery of solar radiation for the purposes of illumination, solar thermal collection etc. . . . Steps can be added to, taken from or modified from the steps in this specification without deviating from the scope of the invention. In general, any flowcharts presented are only intended to indicate one possible sequence of basic operations to achieve a function, and many variations are possible.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention. Thus, it is intended that the present subject matter covers such modifications and variations as come within the scope of the appended claims and their equivalents.

The invention claimed is:

1. A solar energy system comprising:
a substantially planar surface capable of allowing solar radiation to pass through it;
a first primary mirror for reflecting a first portion of the solar radiation;
a first secondary mirror for reflecting the first portion of the solar radiation received from the first primary mirror;
a first photocell for receiving the first portion of the solar radiation reflected by both the first primary mirror and the first secondary mirror, the first photocell converting a substantial amount of the first portion of the solar radiation to usable electricity; and
a second photocell for receiving a second portion of the solar radiation not reflected by the first primary mirror, and for converting a substantial amount of the second portion of the solar radiation to usable electricity;
wherein the second photocell is located between the first photocell and the planar surface.

2. The solar energy system of claim 1, wherein the first solar cell comprises c-Si, CIGS, CdTe, a-Si, polySi, mc-Si.

3. The solar energy system of claim 1, wherein the second photocell is coupled to the planar surface.

4. The solar energy system of claim 1, wherein the second photocell is a flat plate photocell.

5. The solar energy system of claim 1, wherein the second photocell comprises a first surface and a second surface; wherein the first surface receives unreflected solar radiation; and wherein the second surface receives solar radiation reflected from a backside of the first secondary mirror.

6. The solar energy system of claim 1, further comprising:
a second primary mirror for reflecting the second portion of the solar radiation; and
a second secondary mirror for reflecting the second portion of the solar radiation reflected by the second primary mirror;
wherein both the second primary mirror and the second secondary mirror are located between the first secondary mirror and the planar surface; and
wherein the second secondary mirror and the second primary mirror reflect solar radiation to the second photocell.

7. The solar energy system of claim 6, wherein the second photocell is a multi-junction cell for receiving the second portion of the solar radiation.

8. The solar energy system of claim 6, wherein the first secondary mirror is comprised of an optical polymer coating on the outer surface of the second primary mirror.

9. The solar energy system of claim 6, wherein the second primary mirror is located on a back side of the first secondary mirror.

10. A method of making a solar energy system comprising:
providing a substantially planar surface capable of allowing solar radiation to pass through it;
providing a first primary mirror for reflecting a first portion of the solar radiation;
providing a first secondary mirror for reflecting the first portion of the solar radiation reflected by the first primary mirror;
providing a first photocell for receiving the first portion of the solar radiation reflected by both the first primary mirror and the first secondary mirror; and
providing a second photocell for receiving a second portion of the solar radiation not reflected by the first primary mirror;
wherein a first electrical current from the first photocell may be generated; and
wherein a second electrical current from the second photocell may be generated.

11. The method making a solar energy system of claim 10, further comprising the step of providing an electrical circuit, wherein the first and second electrical currents are both coupled to the electrical circuit.

12. The method of making the solar energy system of claim 10, further comprising the steps of:
placing a liquid optical coating in a mold, the mold conforming to the shape of the first secondary mirror and is substantially hyperboloid;
inserting a substrate into the mold, the substrate conforming to the shape of a second primary mirror and is substantially paraboloid;
polymerizing the liquid optical coating; and
applying a mirror surface to the convex surface of the polymerized optical coating.

13. The method of making a solar energy system of claim 6, comprising the steps of:
providing a second primary mirror for reflecting the second portion of the solar radiation; and
providing a second secondary mirror for reflecting the second portion of the solar radiation reflected by the second primary mirror;
wherein both the second primary mirror and the second secondary mirror are located between the first secondary mirror and the planar surface; and
wherein the second secondary mirror and the second primary mirror reflect solar radiation to the second photocell.

14. The method of making the secondary primary mirror of claim 13, further comprising the steps of applying a mirrored surface to the back side of the first primary mirror

15. A solar energy system comprising:
a primary mirror for reflecting a first portion of solar radiation;
a secondary mirror with a first reflective surface and a second reflective surface, wherein the first reflective surface reflects the first portion of solar radiation reflected by the primary mirror, and wherein the second reflective surface reflects a second portion of solar radiation;
a first photocell for receiving the first portion of solar radiation reflected by the first reflective surface; and
a second photocell for receiving the second portion of solar radiation reflected by the second reflective surface.

16. The solar energy system of claim 6, wherein the second photocell is a multi- junction cell for receiving the second portion of solar radiation.
